(19) United States
(12) Patent Application Publication
(10) Pub. No.: US 2006/0224340 A1
(43) Pub. Date: Oct. 5, 2006

(54) WAVEFORM DISPLAY DEVICE CAPABLE OF CONNECTING TO NETWORK

(76) Inventor: Genichi Imamura, Yokohama-shi, Kanagawa (JP)

Correspondence Address: FISH & RICHARDSON P.C., P.O. BOX 1022, MINNEAPOLIS, MN, 55440-1022, US

(21) Appl. No.: 11/277,605

(22) Filed: Mar. 27, 2006

(30) Foreign Application Priority Data
Mar. 30, 2005 (JP) 2005-097431

(51) Int. Cl. G01R 13/02

(52) U.S. Cl. 702/67

(57) ABSTRACT

A waveform monitor comprises: means (35) for generating image data including at least waveform display data of a video signal; means (36) for displaying the image data; means (71) for generating moving image data compressed in a predetermined format from the image data; a converter (38) for packetizing the moving image data; and interface means (39) for outputting the packetized moving image data to a network. The waveform monitor can further comprise means (51) for converting a compressed video signal to uncompressed parallel data, the waveform display data is converted from the parallel data.

### BACKGROUND OF THE INVENTION

The present invention relates to a waveform monitor capable of connecting to a network, more specifically, to the waveform monitor capable of compressing image data displayed on a display and outputting to the network.

(Remote monitoring)

FIG. 1 is a view for schematically explaining a video signal monitoring system. As shown in FIG. 1, the video signal monitoring system includes a computer 1, a network 2, and N waveform monitors 3-1, ..., 3-N. The computer 1 can remotely operate each of the waveform monitors 3 through the network 2, and a software allowing such a remote operation is disclosed in, for example, Leader Electronics Corp., “FS 3019 (Products)”, internet <URL: http://www.leader.co.jp/english/product/fs_3019_e.html>to be mentioned later.

For example, when the computer 1 instructs a certain waveform monitor 3-1 to capture an image displayed on a display of the waveform monitor 3, the waveform monitor 3 sends a captured image in bitmap format to the computer 1 through the network 2 . FIG. 2 is a view showing an example in which a button 4 for instructing to capture an image is displayed on a display of the computer 1. FIG. 3 is a view showing an example in which a window 5 displaying the captured image is displayed on the display of the computer 1.

(On-site Monitoring)

FIG. 4 is a view for schematically explaining a flow of a video signal, for example, in a broadcasting station. As shown in FIG. 4, in a broadcasting station A, an MPEG-TS (Transport Stream) signal flows from a TS output device 11 to a digital modulator 12; the TS signal digital modulated, for example, to an ISDB-T (Integrated Services Digital Broadcasting-Terrestrial Transmission) format flows from the digital modulator 12 to an up-converter 13; and the TS signal further converted to a first predetermined frequency is transmitted from the broadcasting station A. Note that a device which outputs a DV (Digital Video) stream can be used instead of the TS output device 11, and in this case, the DV stream signal is transmitted from the broadcasting station A instead of the TS signal. Although hereinafter, a case of a TS signal will be described, a signal compressed in another format, such as a DV stream signal, may be used instead of the TS signal.

In a broadcasting station B, the transmitted TS signal is converted to a second predetermined frequency by a down-converter 21, and this signal is further demodulated to a TS signal by a digital demodulator 22. The TS signal output from the digital demodulator 22 is input to an analyzer 23, where a transmission status of the TS signal is analyzed.

The analyzer 23 can analyze a transmission status of a video signal compressed in MPEG format represented by a TS signal, and display analysis result thereof. Such an analyzer 23 is disclosed in, for example, U.S. Pat. No. 5,774,497 and U.S. Pat. No. 6,650,719: Hoei Sangyo CO., LTD “DVStation (product information)”, internet <URL: http://www.hoei.co.jp/japan/product/pixelmetrix/dvstation.h tml>; and Tektronix, Inc., “MPEG Test System (Products)”, Internet <URL: http://www.tek.com/site/ps/0, ,2A-14844-INTRO_EN,00.html>,. However, the analyzer 23 cannot display a waveform of the video signal. Therefore, a user could not monitor the waveform of the video signal by using the analyzer 23. In these circumstances, the user has been conventionally to further provide a decoder 24 and a waveform monitor 25.

The TS signal output from the digital demodulator 22 is also input to the decoder 24, and an SDI (Serial Digital Interface) signal converted from the TS signal flows from the decoder 24 to the waveform monitor 25. Such a decoder 24 is disclosed in, for example, a NTT Electronics Corporation, “HDTV Decoder HD1000 (Products)”, internet <URL: http://www.nel-world.com/products/systems/hdtv_en_de.html>to be mentioned later, and such a waveform monitor 24 is disclosed in, for example, Leader Electronics Corp., “LV 5750 (Products)” internet <URL: http://www.leader.co.jp/english/product/lv_{—}5750_e.html>to be mentioned later.

FIG. 5 is a schematic functional block diagram of the waveform monitor 25. As shown in FIG. 5, the SDI signal is converted to parallel data by the converter 31, and the parallel data is converted to the waveform display data by the generator 33. The parallel data may be converted to vectorscope display data and/ or video display data by the generator 33. The display data (for example, waveform display data, vectorscope display data and video display data) generated by the generator 33 flows to an image generator 35, and the user can monitor data displayed on a display 36.

As shown in FIG. 5, the SDI signal is also converted to analysis data by an analyzer 32; the analysis data is converted to analysis display data by the generator 34; and the analysis display data flows to the image generator 35.

The image generator 35 combines the display data (for example, the waveform display data, vectorscope display data and video display data) generated by the generator 33 and the analysis display data generated by the generator 34 to generate one image (frame) data, and outputs it to the display 36. The display 36 displays one image (frame) data. Thereby, the user can monitor the display data (for example, the waveform display data, the vectorscope display data and the video display data) generated by the generator 33 and the analysis display data generated by the generator 34.

Meanwhile, a controller 40 inputs a capture instruction from the computer 1 through the network 2, an interface 39 and an IP converter 38, and outputs the capture instruction to an image capturer 37. The image capturer 37 inputs the same data as the image (frame) data inputted to the display 36. The image capturer 37 generates still data in BMP format from the inputted image (frame) data according to the capture instruction from the computer 1. The still data is displayed on the display of the computer 1, thereby allowing remote monitoring.

### SUMMARY OF THE INVENTION

When an image displayed on a display of a waveform monitor was remotely monitored, the image outputted from the waveform monitor was a still image in bitmap format. The image displayed on the display of the waveform monitor is generally a 24-bit image in XGA (1024×768 pixels) format, and has 18,874,368-bit (1024×768×24) information. Therefore, it took approximately 10 seconds for the computer to instruct to capture one image and receive the image from the waveform monitor. As a result, the computer could not timely remote-monitor the image displayed on the display of the waveform monitor.

In addition, a video signal monitoring system was required to further include an analyzer and/ or a decoder to monitor a transmission status and/ or a waveform status of a compressed transmission signal (a TS signal, a DV stream signal, or the like).

An object of the present invention is to provide a waveform monitor for timely remote-monitoring the image displayed on the display.

Another object of the present invention is to provide the waveform monitor for timely remote-monitoring the transmission status and/ or the waveform status of the compressed transmission signal.

Other objects of the present invention will be apparent to one skilled in the art by reference to claims, embodiments of the invention to be described later, and drawings.

A waveform monitor of the present invention includes: means (35) for generating image data including at least waveform display data of a video signal; means (36) for displaying the image data; means (71) for generating moving image data compressed in a predetermined format from the image data; a converter (38) for packetizing the moving image data; and interface means (39) for outputting the packetized moving image data to a network.

The waveform monitor may further include means (51) for converting a compressed video signal to uncompressed parallel data; and the waveform display data is converted from the parallel data. The waveform monitor may further include means (52) for analyzing a transmission status of the compressed video signal and generating analysis data; and the image data includes the analysis data.

Further, a system of the present invention includes the waveform monitor, the network and a computer, in which the computer includes: means (94) for inputting the packetized moving image data from the network; means (93) for depacketizing the packetized moving image data; and means (91) for displaying the moving image data.

Since an image outputted from a waveform monitor is compressed, a computer can receive the image substantially without damaging information as a moving image. Further, since the image outputted from the waveform monitor is a moving image, the computer can adequately remote-monitor the image displayed on the display of the waveform monitor. Other advantages will be apparent for a skilled person in the art by reference to claims, embodiments of the invention to be described later, and drawings.

### BRIEF DESCRIPTION OF THE DRAWINGS

FIG. 1 is a view for schematically explaining a video signal monitoring system;

FIG. 2 is a view showing an example in which a button 4 for instructing to capture an image is displayed on a display of a computer 1;

FIG. 3 is a view showing an example in which a window 5 displaying a captured image is displayed on the display of the computer 1;

FIG. 4 is a view for schematically explaining a flow of a video signal, for example, in a broadcasting station;

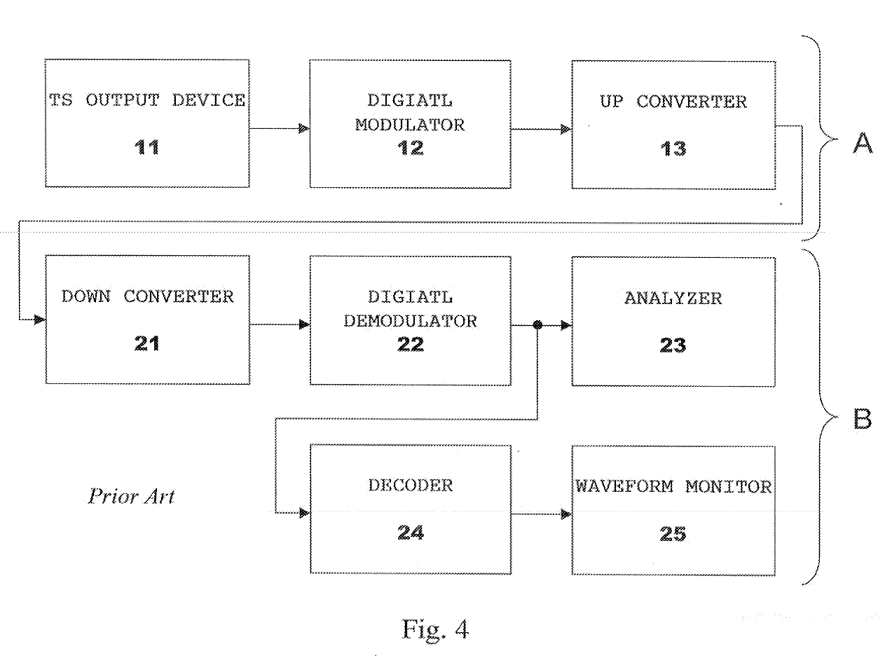

FIG. 5 is a schematic functional block diagram of a waveform monitor 25;

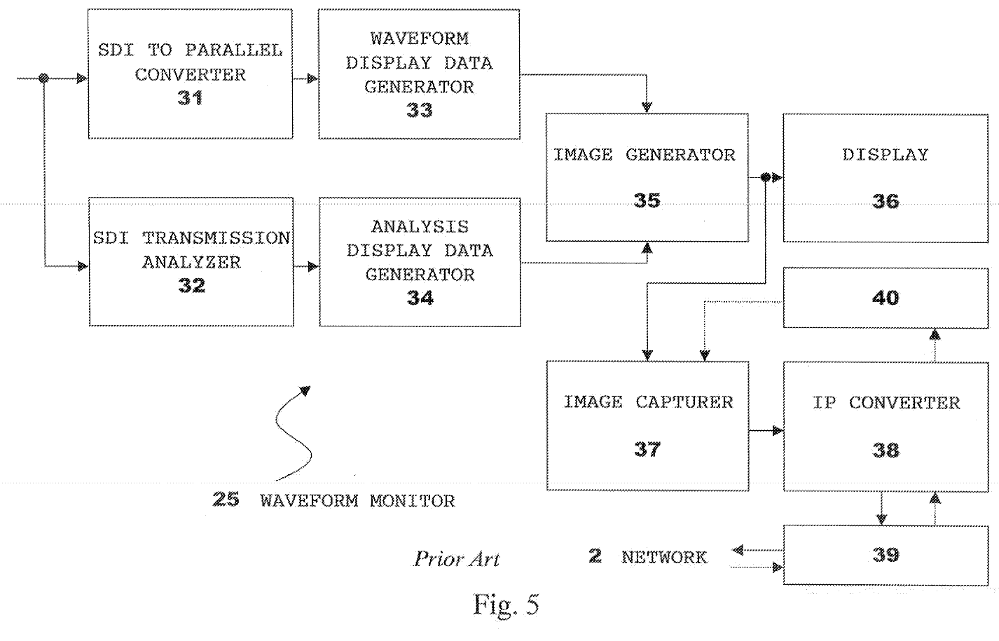

FIG. 6 is a view showing an example in which waveform display data, vectorscope display data and video display data generated by a generator 33, and analysis display data generated by a generator 34 are displayed;

FIG. 7 is a schematic functional block diagram of a waveform monitor 41 of the present invention;

FIG. 8 is a view for schematically explaining a video signal monitoring system according to the present invention;

FIG. 9 is a schematic functional block diagram of the computer 1;

FIG. 10 is another schematic functional block diagram of the waveform monitor 41 of the present invention; and

FIG. 11 is a view showing an example displayed on a display 36 and a window in the display of the computer 1.

### DETAILED DESCRIPTION OF THE INVENTION

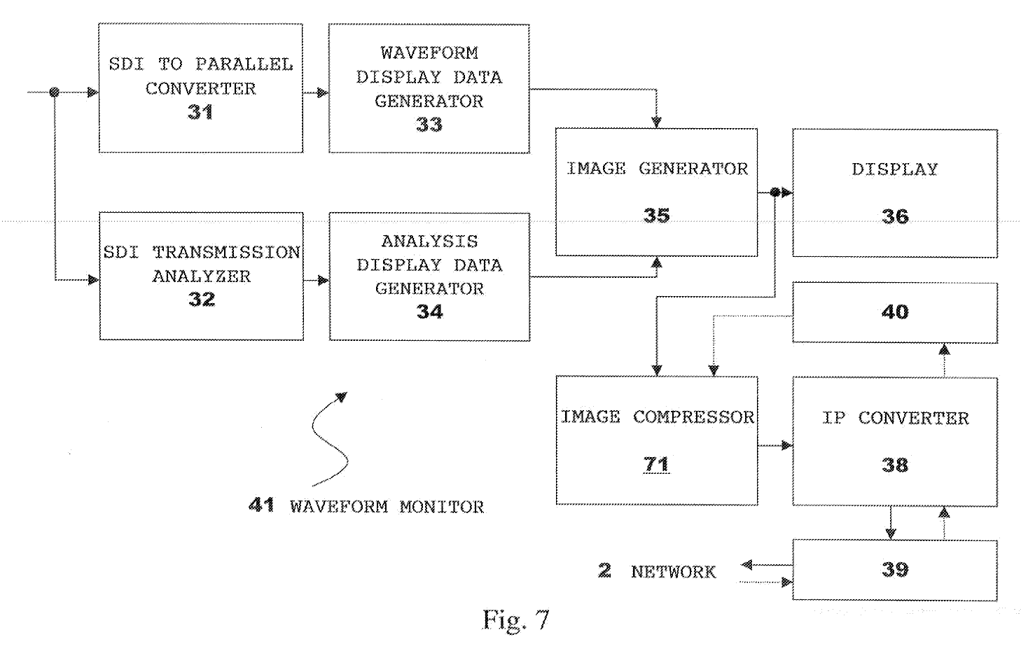

FIG. 7 is a schematic functional block diagram of a waveform monitor 41 of the present invention. As shown in FIG. 7, the waveform monitor 41 includes a converter 31, a generator 33, an analyzer 32, a generator 34, an image generator 35, a display 36, an IP converter 38, an interface 39 and a controller 40, as in the conventional waveform device. Further, the waveform monitor 41 includes an image compressor 71 instead of an image capturer 37.

The converter 31 converts an SDI signal into parallel data; and the generator 33 converts the parallel data into waveform display data. The generator 33 preferably also converts the parallel data into vectorscope display data and/or video display data. Note that the generator 33 may generate other display data from the parallel data. The generator 33 outputs the display data (for example, a waveform display, a vectorscope display data and a video display data) to the image generator 35. When the generator 33 outputs a plurality of display data, the generator 33 may combine the plurality of display data.

The analyzer 32 analyzes a transmission status of the SDI signal, generates analysis data, and outputs the same to the generator 34. The generator 34 converts (combines) the analysis data into analysis display data, and outputs the same to the image generator 35.

The image generator 35 combines the display data generated by the generator 33 (for example, the waveform display data, the vectorscope display data and the video display ) and the analysis display data generated by the generator 34 to generate one image (frame) data, and outputs it to the display 36 and the image compressor 71.

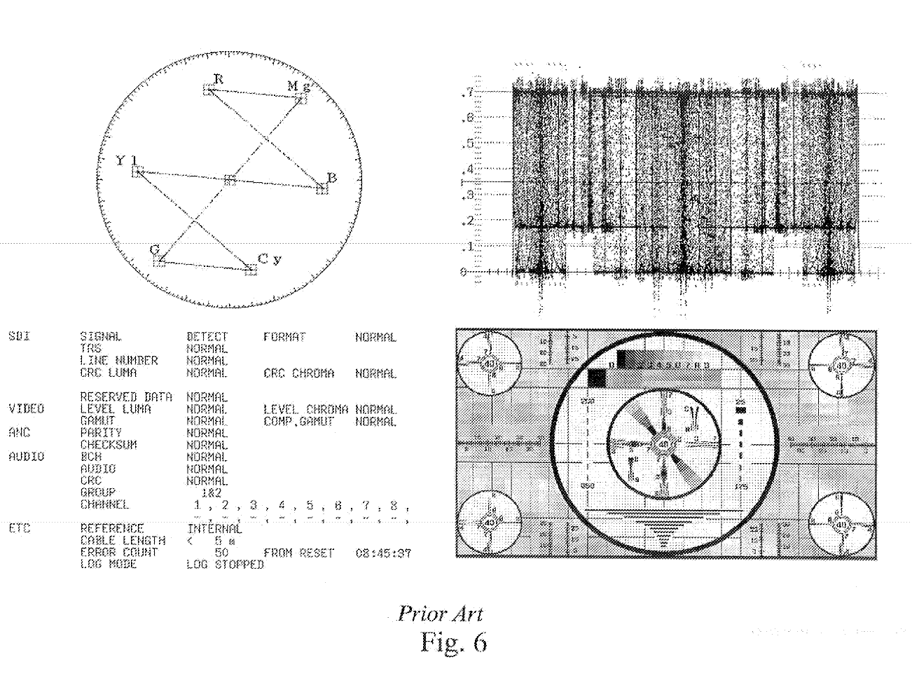

The display 36 displays the one image (frame) data, as in the conventional display (refer to FIG. 6). As shown in FIG. 6, the waveform display (upper right), the vectorscope display (upper left), the video display (lower right), and an analysis result display (lower left) are simultaneously displayed as appropriate. However, the waveform display, the vectorscope display, the video display and the analysis result display are not necessarily displayed simultaneously. That is to say, when only a waveform display is selected by a user, the generator 33 generates only waveform display data; the generator 34 stops the function thereof; and the generator 35 inputs the display data (only the waveform display data) generated by the generator 33 as one image (frame) data and outputs the same to the display 36 and the image compressor 71.

Meanwhile, when the display 36 displays 60 images (frames) data per second, each of the generators 33, 34 and 35 outputs 60 data per second.

The image compressor 71 inputs the same data as the image (frame) data inputted to the display 36. The image compressor 71 generates moving image data compressed in a predetermined format (for example, an MPEG format, a DV format, an AVI format, a MotionJPEG format, or the like) from the inputted image (frame) data, according to capture instructions from a computer 1, and outputs the moving image data to the IP converter 38.

The IP converter 38 conforms the moving image data compressed in a predetermined format to IP, and outputs the same to a network 2 through the interface 39. The IP converter 38 generally packetizes data to be outputted, according to a TCP/IP (Transmission Control Protocol/Internet Protocol) standard.

An Ethernet is generally used as the interface 39, and preferably the interface 39 has performance the same as or better than 100BASE-T. Although the network 2 is generally a LAN, the network 2 may be the Internet if the interface 39 has an Internet connecting function.

The controller 40 inputs the capture instruction from the computer 1 through the network 2, the interface 39 and the IP converter 38, and outputs the capture instruction to the image capturer 37. Specifically, the IP converter 38 outputs packetized capture instruction data from the network 2 through the interface 39. The IP converter 38 further depacketizes the packetized capture instruction data, and outputs the same to the controller 40. The controller 40 outputs the capture instruction data to the image compressor 71.

Although each of the generators 33, 34 and 35 has been herein described as a separate functional block, these generators 33, 34 and 35 may be configured as one CPU. Alternatively, each of the generators 33, 34 and 35 may be configured as one CPU. Further, the converter 31 and the analyzer 32 may also be configured as one CPU together with the generators 33, 34 and 35. In addition, the compressor 71, the converter 38 and the controller 40 also may be configured as one CPU together with the generators 33, 34 and 35.

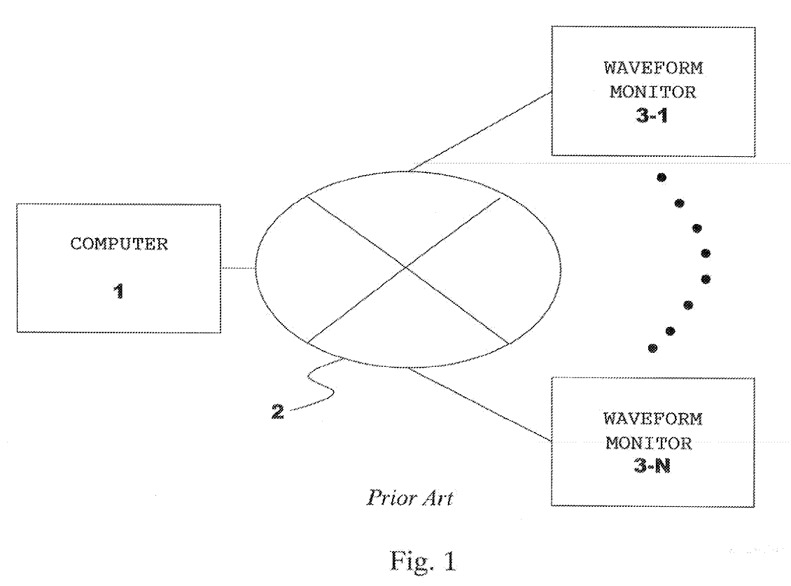

By replacing at least one of a plurality of the waveform monitors 3 shown in FIG. 1 with the waveform monitor 41 of the present invention, a system according to the present invention can be established. Preferably, all of the waveform monitors 3 shown in FIG. 1 are replaced with the waveform monitors 41.

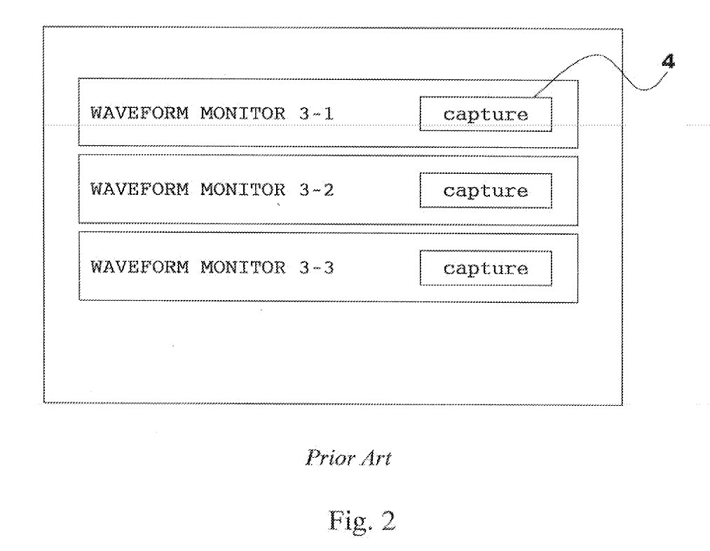

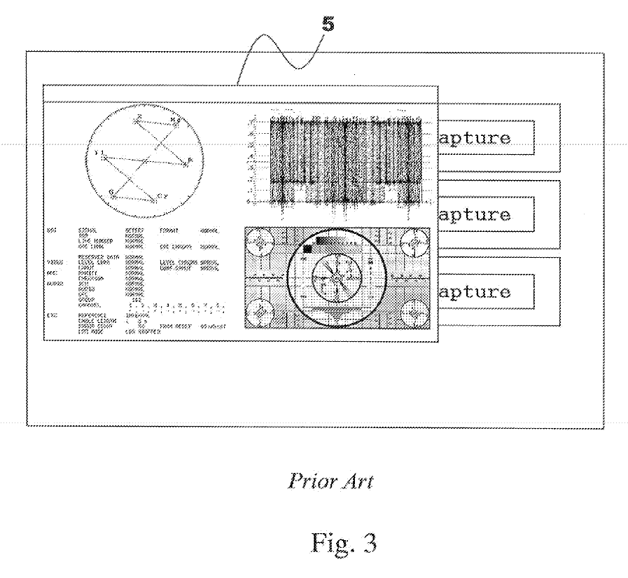

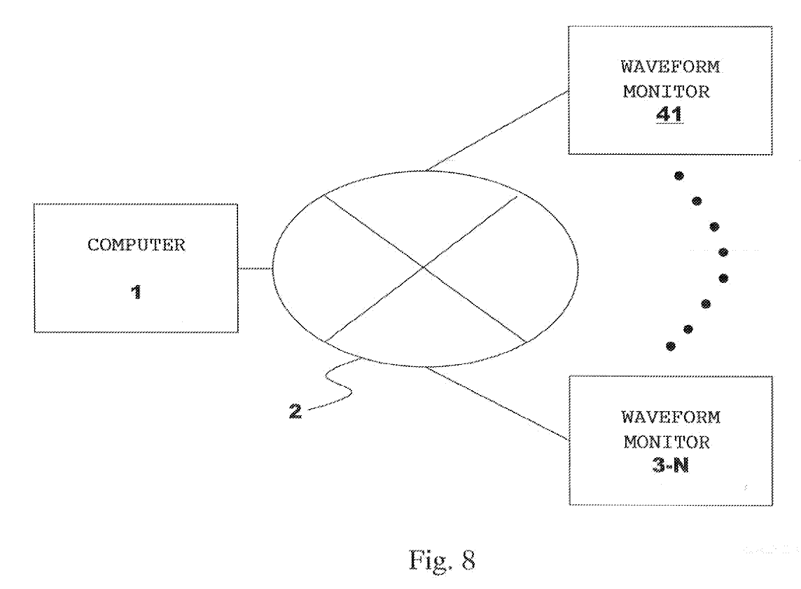

For example, a system, in which only the waveform monitor 3-1 shown in FIG. 1 is replaced with the waveform monitor 41 of the present invention, will be described hereinafter. FIG. 8 is a view for schematically explaining a monitoring of a video signal according to the present invention. A button 4 for instructing to capture an image is displayed on the display of the computer 1, as in FIG. 2. When the computer 1 instructs the waveform monitor 41 to capture images displayed on the display 36 of the waveform monitor 41, the waveform monitor 41 sends captured images to the computer 1 through the network 2 as moving image data compressed in a predetermined format. The computer 1 plays the moving image data in the window as in FIG. 3.

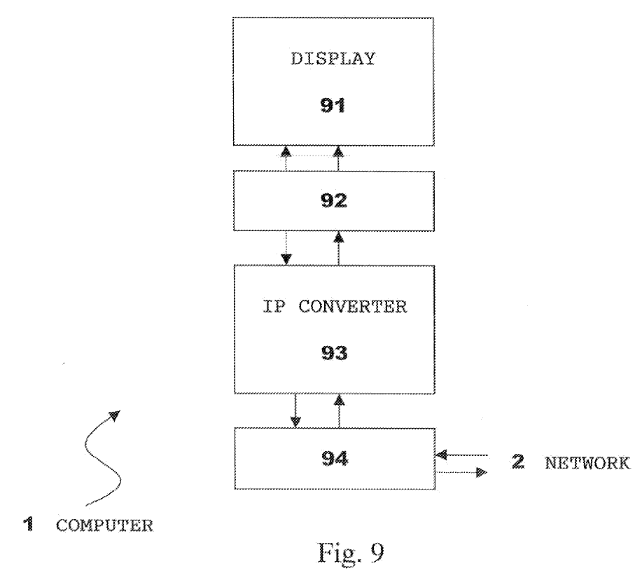

FIG. 9 is a schematic functional block diagram of the computer 1. The computer 1 includes a display 91, a controller 92, an IP converter 93 and an interface 94. The controller 92 outputs data for representing at least one waveform monitor connected to the network 2, and data for representing the button 4 for instructing to capture an image displayed on the display of the waveform monitor. For example, when the button 4 corresponding to the waveform monitor 41 is selected, the controller 92 outputs data for instructing to capture the images displayed on the display 36 of the waveform monitor 41 to the IP converter 93. The IP converter 93 packetizes the capture instruction data according to, for example, the TCP/IP standard, and outputs the same to the network 2 through the interface 94 (the Ethernet, for example).

Further, the IP converter 93 inputs the packetized moving image data from the waveform monitor 41 from the network 2 through the interface 94. The IP converter 93 further depacketizes the packetized moving image data and outputs to the controller 92. The controller 92 plays the moving image data on the display 91.

Although each of the controller 92 and the IP converter 35 has been herein described as a separate functional block, they may be configured as one CPU.

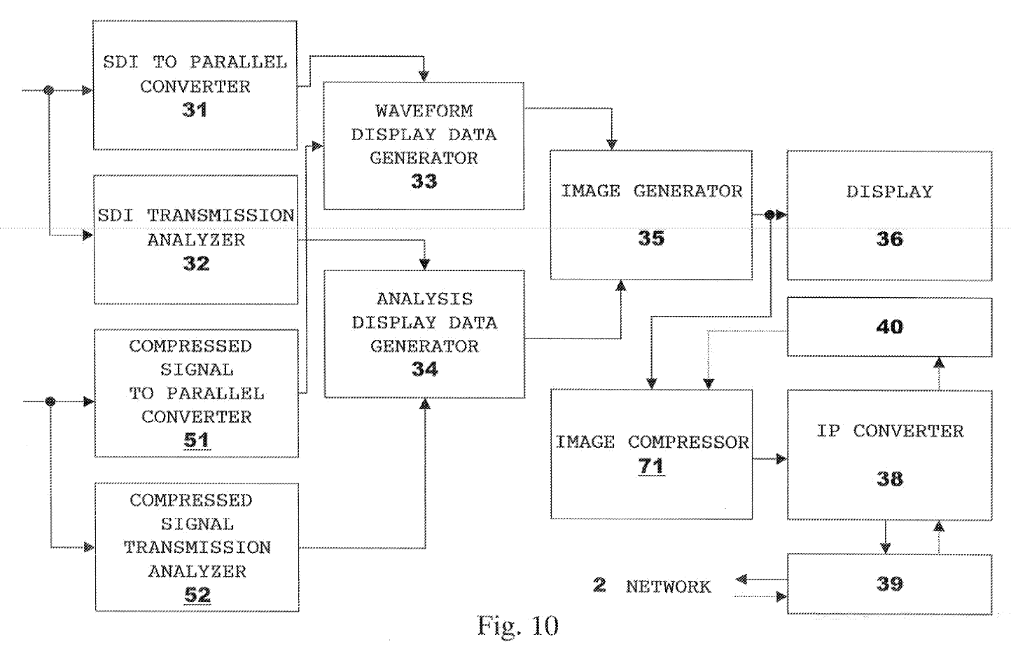

Meanwhile, in a broadcasting station, for example, there exists not only an SDI signal but also a compressed transmission signal (a TS signal, a DV stream signal, or the like). Therefore, the waveform monitor 41 preferably processes the compressed transmission signal. FIG. 10 is another schematic functional block diagram of the waveform monitor 41 of the present invention. As shown in FIG. 10, the waveform monitor 41 inputs a compressed transmission signal at a converter 51 and an analyzer 52, and inputs an SDI signal at the converter 31 and the analyzer 32. Note that operations of the converter 31 and the analyzer 32 are similar to those described with reference to FIG. 7.

The converter 51 converts the compressed transmission signal to parallel data, and outputs the same to the generator 33. When a compressed transmission signal is selected by a user, the generator 33 converts the parallel data from the converter 51 to the waveform display data (and preferably vectorscope display data and/or video display data), and outputs the same to the image generator 35. When an SDI signal is selected by the user, operation of the generator 33 is similar to that described with reference to FIG. 7.

The analyzer 52 analyses a transmission status of the compressed transmission signal, generates analysis data, and outputs the same to the generator 34. When the compressed transmission signal is selected by the user, the generator 34 converts (combines) the analysis data from the analyzer 32 to analysis display data, and outputs the same to the image generator 35. When the SDI signal is selected by the user, the operation of the generator 34 is similar to that of the generator 53 described with reference to FIG. 7. Operations of other means are similar to those of the means described with reference to FIG. 7.

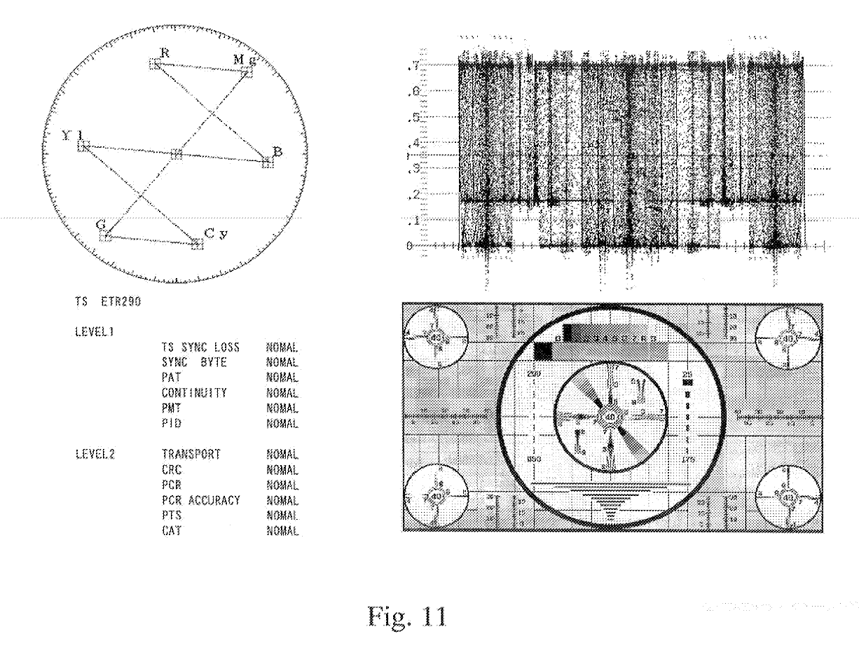

When the compressed transmission signal is a TS signal, and the TS signal is selected by the user, and further, the waveform display, the vectorscope display, the video display and the analysis result display are selected by the user, the display 36 and the window in the display of the computer 1 display as shown in FIG. 11, for example. In FIG. 11, the waveform display is displayed in an upper-right portion, the vectorscope display is displayed in an upper-left portion, the video display is displayed in a lower-right portion and the analysis result (items defined by the ETR290 recommended by the ETSI (European Telecommunications Standards Institute)) display is displayed in a lower-left portion.

Note that the present invention is not limited to the above-described embodiments, and a skilled person in the art can easily modify the above-described embodiments without departing from the scope of claims of the invention.

What is claimed is:

1. A waveform monitor comprising:
means (35) for generating image data including at least waveform display data of a video signal;
means (36) for displaying the image data;
means (71) for generating moving image data compressed in a predetermined format from the image data;
a converter (38) for packetizing the moving image data; and
interface means (39) for outputting the packetized moving image data to a network.

2. The waveform monitor according to claim 1, further comprising:
means (51) for converting a compressed video signal to uncompressed parallel data, wherein the waveform display data is converted from the parallel data.

3. The waveform monitor according to claim 2, further comprising:
means (52) for analyzing a transmission status of the compressed video signal and generating analysis data, wherein the image data includes the analysis data.

4. The waveform monitor according to claim 1, further comprising:
means (52) for analyzing a transmission status of a compressed video signal and generating analysis data, wherein the image data includes the analysis data.

5. A system including a waveform monitor, a network and a computer, wherein
the waveform monitor comprises:
means (35) for generating image data including at least waveform display data of a video signal;
means (36) for displaying the image data;
means (71) for generating moving image data compressed in a predetermined format from the image data;
a converter (38) for packetizing the moving image data; and
interface means (39) for outputting the packetized moving image data to the network, and
the computer comprises:
means (94) for inputting the packetized moving image data from the network;
means (93) for depacketizing the packetized moving image data; and
means (91) for displaying the moving image data.
